(19) United States
(12) Patent Application Publication
(10) Pub. No.: US 2026/0181946 A1
(43) Pub. Date: Jun. 25, 2026

(54) METAL OXIDE THIN FILM TRANSISTOR AND MANUFACTURING METHOD THEREOF

(71) Applicant: Peking University Shenzhen Graduate School, Nanshan District (CN)

(72) Inventors: Lei Lu, Shenzhen P.R. (CN); Mengran Liu, Shenzhen P.R. (CN); Zhendong Jiang, Shenzhen P.R. (CN); Yunping Wang, Shenzhen P.R. (CN); Shengdong Zhang, Shenzhen P.R. (CN)

(21) Appl. No.: 19/011,180

(22) Filed: Jan. 6, 2025

(30) Foreign Application Priority Data
Dec. 25, 2024 (CN) 202411925856X

(51) Int. Cl. H10D 30/67; H10D 30/01

(52) U.S. Cl. CPC H10D 30/6704; H10D 30/031; H10D 30/6756

(57) ABSTRACT

The present application relates to an oxide thin film transistor, comprising a substrate; an active layer, located on the substrate, comprising a channel region and a source region and a drain region; a hydrogen absorbing layer, located on the active layer, wherein a portion of the hydrogen absorbing layer located on the channel region is removed; a hydrogen-rich sealing insulation layer, located on the hydrogen absorbing layer, wherein a portion of the hydrogen-rich sealing insulation layer located above the channel region is removed; a top gate dielectric layer, located on the hydrogen-rich sealing insulation layer and the channel region of the active layer; a top gate, located on the top gate dielectric layer; and a source electrode and a drain electrode, respectively in contact with the hydrogen absorbing layer on both sides of the channel region.

### CROSS-REFERENCE TO RELATED APPLICATIONS

The present application claims priority to Chinese Patent Application No. 202411925856X titled “A Metal Oxide Thin Film Transistor and Manufacturing Method Thereof” and filed Dec. 25, 2024, the entirety of which is incorporated by reference hereto.

### TECHNICAL FIELD

The present application relates to the field of microelectronics, and more particularly, to a metal oxide thin film transistor and manufacturing method thereof.

### BACKGROUND

Small size metal oxide semiconductor thin film transistors (TFTs) are widely used and play an important role in consumer electronics, such as intelligent wearable electronics, by virtue of their high efficiency and flexibility, and their performance requirements become more and more stringent.

A conventional metal oxide semiconductor thin film transistor (TFTs) structure mainly includes a back-gate structure and a self-aligned top gate structure. There is a large overlap capacitance between the source and drain and the gate of the back-gate structure TFT, and the overlap capacitance has a great influence on the operating speed of the TFT device with the size being continuously reduced. In contrast, the self-aligned gate-source/drain TFT structure is more suitable for small size TFT devices due to the absence of overlap capacitance. In self-aligned gate-source/drain TFT structures, the high conductivity of the source region and the drain region is typically achieved by introducing a large number of defects through the argon (Ar) plasma bombardment of the source region and the drain region. As the size of TFT devices is further reduced, the influence of diffusion of source and drain defects on the channel cannot be ignored, which results in a negative shift of threshold voltage, thus affecting the switching capability of TFT devices. In addition, the thermal stability of the introduced source-drain defects is poor, which limits the application of top-gate self-aligned TFT in three-dimensional integrated circuits with complex thermal processes.

### SUMMARY

In order to solve the problems in the existing technology, the present application provides an oxide thin film transistor, comprising: a substrate; an active layer, located on the substrate, comprising a channel region and a source region and a drain region; a hydrogen absorbing layer, located on the active layer, wherein a portion of the hydrogen absorbing layer located on the channel region is removed; a hydrogen-rich sealing insulation layer, located on the hydrogen absorbing layer, wherein a portion of the hydrogen-rich sealing insulation layer located above the channel region is removed; a top gate dielectric layer, located on the hydrogen-rich sealing insulation layer and the channel region; a top gate, located on the top gate dielectric layer; a source electrode and a drain electrode, respectively in contact with the hydrogen absorbing layer on both sides of the channel region.

Specifically, the oxide thin film transistor provided in the present application, the key point of its structure is that, the hydrogen absorbing layer is capable of absorbing hydrogen in the channel region and the hydrogen-rich sealing insulation layer, forming a highly resistive channel region, and improving the conductivity of the source region and the drain region.

Specifically, the oxide thin film transistor provided in the present application, the key point of its structure is also that, a relatively thick hydrogen-rich sealing insulation layer is introduced under the top gate dielectric layer, so that the overlap capacitance between the top gate and the source region and the drain region is negligibly small, forming a pseudo-self-aligned device structure.

Specifically, the oxide thin film transistor further comprising: a hydrogen barrier layer, located on the substrate; a buffer layer, located on the hydrogen barrier layer, wherein, the active layer is located above the buffer layer.

Specifically, the oxide thin film transistor further comprising: a back gate electrode, located on the buffer layer; a back gate dielectric layer, located on the buffer layer and the back gate electrode; wherein, the active layer is located on the back gate dielectric layer.

Specifically, the source electrode and the drain electrode are further in contact with the source region and the drain region below the hydrogen absorbing layer respectively.

Specifically, the width of the top gate is greater than the width of the channel region.

Specifically, the material of the active layer includes an amorphous metal oxide, and the material of the hydrogen absorbing layer includes an indium-rich metal oxide.

Specifically, the material of the hydrogen-rich sealing insulation layer includes hydrogen-rich silicon nitride.

Specifically, the top gate dielectric layer is an air permeable insulating material.

The present application further provides a manufacturing method of an oxide thin film transistor, comprising: manufacturing a substrate; depositing an active layer on the substrate, and patterning the active layer; depositing a hydrogen absorbing layer on the active layer; depositing a hydrogen-rich sealing insulation layer on the hydrogen absorbing layer; patterning the hydrogen absorbing layer and the hydrogen-rich sealing insulation layer, removing the hydrogen absorbing layer on the channel region and the hydrogen-rich sealing insulation layer above the channel region, and exposing the channel region; depositing a top gate dielectric layer on the channel region of the active layer and the hydrogen-rich sealing insulation layer, and performing an annealing operation; patterning the top gate dielectric layer and the hydrogen-rich sealing insulation layer to form source and drain electrode contact holes; depositing and patterning a metal layer on the top gate dielectric layer, to form a top gate, and a source electrode and a drain electrode penetrating at least into the source and drain electrode contact holes.

Specifically, the manufacturing method of an oxide thin film transistor, further comprising: depositing a hydrogen barrier layer on the substrate; depositing a buffer layer on the hydrogen barrier layer; depositing the active layer on the buffer layer, and patterning the active layer.

The present application further provides a manufacturing method of an oxide thin film transistor, comprising: manufacturing a substrate; depositing a buffer layer on the substrate; depositing and patterning a first metal layer on the buffer layer, to form a back gate; depositing a back gate dielectric layer on the back gate and the buffer layer; depositing an active layer on the back gate dielectric layer, and patterning the active layer; depositing a hydrogen absorbing layer on the active layer; depositing a hydrogen-rich sealing insulation layer on the hydrogen absorbing layer; patterning the hydrogen absorbing layer and the hydrogen-rich sealing insulation layer, removing the hydrogen absorbing layer on the channel region and the hydrogen-rich sealing insulation layer above the channel region, and exposing the channel region; depositing a top gate dielectric layer on the channel region of the active layer and the hydrogen-rich sealing insulation layer, and performing an annealing operation; patterning the top gate dielectric layer and the hydrogen-rich sealing insulation layer, to form source and drain electrode contact holes; depositing and patterning a second metal layer on the top gate dielectric layer, to form a top gate, and a source electrode and a drain electrode penetrating at least into the source and drain electrode contact holes.

Specifically, the manufacturing method of an oxide thin film transistor, further comprising: depositing a hydrogen barrier layer on the substrate; depositing a buffer layer on the hydrogen barrier layer.

### BRIEF DESCRIPTION OF THE DRAWINGS

Hereinafter, preferred embodiments of the present application will be described in further detail with reference to the accompanying drawings, in which:

FIG. 1a to FIG. 1b are cross-sectional views of the structure of a thin film transistor according to an embodiment of the present application;

FIG. 2 is a flow diagram of a manufacturing method of a thin film transistor according to an embodiment of the present application;

FIG. 3a to FIG. 3h are manufacturing state diagrams of the thin film transistor of the embodiment shown in FIG. 1a to FIG. 1b;

FIG. 4a to FIG. 4b are cross-sectional views of the structures of a thin film transistor according to another embodiment of the present application;

FIG. 5 is a flow diagram of a manufacturing method of a thin film transistor according to another embodiment of the present application;

FIG. 6a to FIG. 6h are manufacturing state diagrams of the thin film transistor of the embodiment shown in FIG. 4a to FIG. 4b.

### DESCRIPTION OF DISCLOSURE

For the purposes, technical solutions and advantages of the embodiments of the present application to become clearer, the technical solutions in the embodiments of the present application will be clearly and completely described in conjunction with the accompanying drawings in the embodiments of the present application, and it is obvious that the described embodiments are a part of the embodiments of the present application rather than all the embodiments. Based on the embodiments in the present application, all the other embodiments obtained by a person of ordinary skill in the art without making any inventive effort fall within the scope of protection of the present application.

In the following detailed description, reference may be made to the various specification accompanying drawings that used as part of the present application to illustrate particular embodiments of the present application. In the accompanying drawings, similar marks depict substantially similar components in different figures. Various particular embodiments of the present application are described below in sufficient detail, so that general technicians with relevant knowledge and skills in this field are able to implement the technical solutions of the present application. It should be understood that other embodiments may be utilized or structural, logical, or electrical changes may be made to the embodiments of the present application.

For techniques, methods and equipment known to general technicians in relevant fields may not be discussed in detail, but where appropriate, the techniques, methods and equipment described should be considered as part of the specification. The connecting lines between the units in the accompanying drawings are for illustrative purposes only, and indicate that the units at least at both ends of the lines are in communication with each other, and are not intended to limit the inability of the unconnected units to communicate with each other. In addition, the number of lines between the two units is intended to indicate at least the number of signals related or at least the outputs available for communication between the two units, and is not intended to limit the communication between the two units to only the signals as shown in the figure.

Transistor may refer to a transistor of any structure, such as a field effect transistor (FET) or a bipolar junction transistor (BJT). When the transistor is a field effect transistor, depending on the different channel material, it can be hydrogenated amorphous silicon, metal oxides, low-temperature polycrystalline silicon, organic transistors, and so forth. Depending on whether the carriers are electrons or holes, transistors can be categorized as N type transistors and P type transistors, whose control pole is the gate of the field effect transistor, and the first pole can be the drain or source of the field effect transistor, the corresponding second pole can be the source or drain of the field effect transistor, and the control pole or the third pole can be the gate; when the transistor is a bipolar junction transistor, the control pole is the base of the bipolar junction transistor, the first pole may be the collector or emitter of the bipolar junction transistor, the corresponding second pole may be the emitter or collector of the bipolar junction transistor, and the control pole or the third pole may be the base. Transistors can be produced using amorphous silicon, polycrystalline silicon, oxide semiconductors, organic semiconductors, NMOS/PMOS processes or CMOS processes.

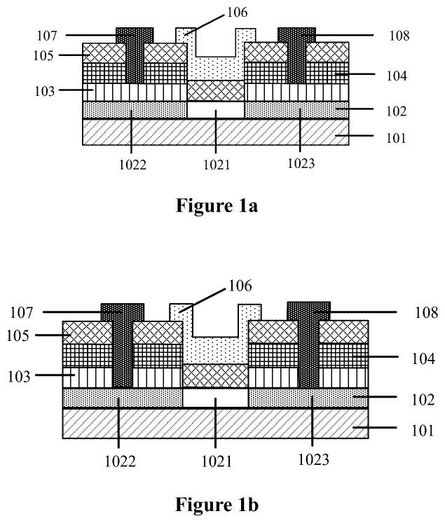

FIG. 1a to FIG. 1b are cross-sectional views of the structure of an oxide thin film transistor according to an embodiment of the present application.

According to an embodiment, the oxide thin film transistor may comprise a substrate 101. In an embodiment of the present application, the substrate 101 may comprise PEN or other flexible insulating material such as PI, PET, and may also comprise a rigid material such as rigid substrate silicon, glass, and so forth.

According to an embodiment, the oxide thin film transistor may further comprise an active layer 102, which is located on the substrate 101, and the material of the active layer 102 may comprise amorphous indium gallium zinc oxide (a-IGZO), amorphous indium zinc oxide (a-IZO), amorphous indium gallium oxide (a-IGO), and so forth, and has a thickness of not less than 1 nm. The active layer 102 may comprise a channel region 1021, a source region 1022 and a drain region 1023.

According to an embodiment, the oxide thin film transistor may further comprise a hydrogen absorbing layer 103, located on the active layer 102. The hydrogen absorbing layer 103 comprises two portions separated from each other, and the hydrogen absorbing layer above the channel region 1021 is removed. The hydrogen absorbing layer 103 may include indium-rich metal oxide having a good conductivity, such as indium zinc oxide (IZO) or indium oxide (In₂O₃) having a high indium composition.

According to an embodiment, the oxide thin film transistor may further comprise a hydrogen-rich sealing insulation layer 104, located on the hydrogen absorbing layer 103. The material of hydrogen-rich sealing insulation layer 104 may include, for example, hydrogen-rich silicon nitride (Si₃N₄:H) and the like. The hydrogen-rich sealing insulation layer 104 comprises two portions separated from each other, and the hydrogen-rich sealing insulation layer above the channel region 1021 is removed.

Since hydrogen has high chemical activity, can combine with oxygen in the indium-rich metal oxide to form an H—O bond or with In in the indium-rich metal oxide to form an In—H bond, therefore the hydrogen absorbing layer 103 can absorb hydrogen impurities. In addition, besides absorbing hydrogen impurities in the channel region 1021 and hydrogen-rich sealing insulation layer 104, increasing the concentration of the carriers in the source region and the drain region, the hydrogen absorbing layer 103 can also directly contact with the metal oxide in the source region and the drain region of the active layer 102, so as to further improve the conductivity of the source region and the drain region.

According to an embodiment, the hydrogen absorbing layer 103 is capable of absorbing hydrogen impurities from the hydrogen-rich sealing insulation layer 104 and the channel region 1021, ensuring a low hydrogen content of the channel region 1021, and forming a highly resistive channel region. The hydrogen absorbing layer 103 absorbs hydrogen impurities, and the hydrogen content is increased, while the hydrogen content in the source region 1022 and the drain region 1023 is lower. Thus, a concentration gradient is created between hydrogen contents in the hydrogen absorbing layer 103 and that in the source region 1022, the drain region 1023. Under the influence of concentration gradient and temperature, the hydrogen impurities absorbed by the hydrogen absorbing layer 103 diffuse into the source region 1022 and the drain region 1023, to form highly conductive source region and drain region, thereby precisely regulating the distribution of hydrogen in the metal oxide, reducing the hydrogen content in the channel region 1021, and increasing the hydrogen content in the source region 1022 and the drain region 1023. Such a structure can improve the conductivity of the source region and the drain region, avoid the process of forming highly conductive source region and drain region by defects generated by plasma bombardment in the existing schemes, and avoid the influence of source and drain defects on the channel region.

According to an embodiment, the oxide thin film transistor may further comprise a top gate dielectric layer 105, located on the hydrogen-rich sealing insulation layer 104 and the channel region 1021. The material of the top gate dielectric layer 105 may include a material having air permeability such as silicon dioxide (SiO₂), aluminum oxide (Al₂O₃), hafnium oxide (HfOₓ), and so forth. The hydrogen of the channel region 1021 may also be vented out through the top gate dielectric layer 105 during the transistor manufacturing process, ensuring a low hydrogen content of the channel region 1021.

According to an embodiment, the oxide thin film transistor may further comprise a top gate 106, having a width greater than the width of the channel region 1021. There is some amount of overlap between the top gate 106 and the source region 1022, the drain region 1023. However, a hydrogen-rich sealing insulation layer 104 having a thickness of not less than 100 nm is introduced under the top gate dielectric layer 105, so that the overlap capacitance between the top gate 106 and the source region 1022, drain region 1023 is negligibly small, forming a pseudo-self-aligned device structure.

According to an embodiment, the oxide thin film transistor may further comprise a source electrode 107 and a drain electrode 108. The materials of the source electrode 107 and the drain electrode 108 may include metal molybdenum (Mo), having a thickness of not less than 20 nm.

According to an embodiment, as shown in FIG. 1b, the source electrode 107 and the drain electrode 108 may extend downward, and directly contact the source region and the drain region in the active layer 102 respectively.

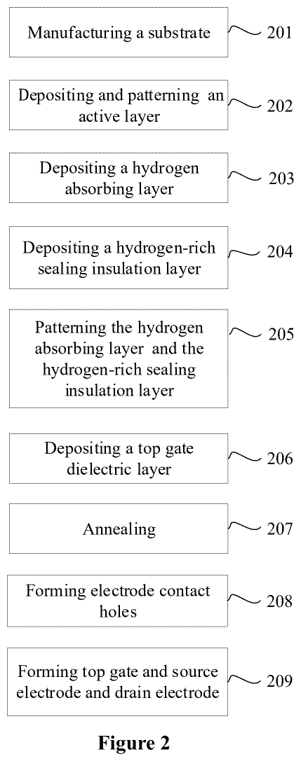

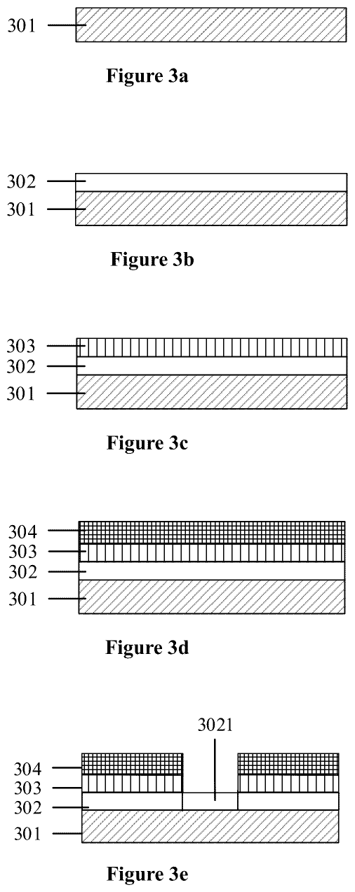

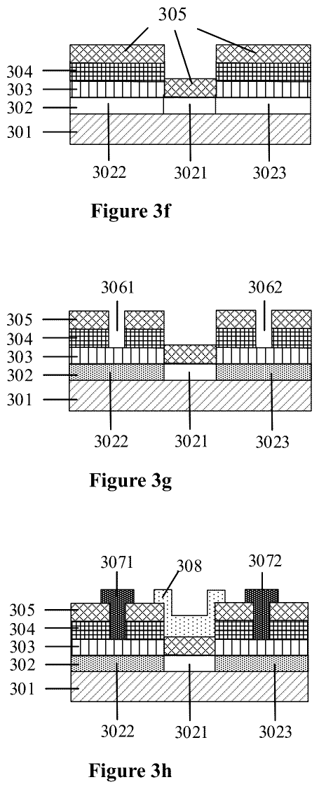

FIG. 2 is a flow diagram of a manufacturing method of a thin film transistor according to an embodiment of the present application. FIG. 3a to FIG. 3h are manufacturing state diagrams of the thin film transistor of the embodiment shown in FIG. 1a to FIG. 1b.

Step 201: as shown in FIG. 3a, a substrate 301 is manufactured.

Step 202: as shown in FIG. 3b, an active layer 302 is deposited on the substrate 301, the material of the active layer 302 may include a-IGZO, a-IZO, a-IGO, and so forth, and the thickness thereof is not less than 1 nm, and then the active layer is patterned by a photolithography process to form active islands.

Step 203, as shown in FIG. 3c, a hydrogen absorbing layer 303 is deposited on the active layer 302. Since the indium (In)-rich material has a strong binding ability with hydrogen, the material of the hydrogen absorbing layer 303 may include an indium-rich metal oxide with good conductivity, such as IZO or In₂O₃ having a high indium composition, and with a thickness of not less than 1 nm.

Step 204, as shown in FIG. 3d, a hydrogen-rich sealing insulation layer 304 is deposited on the hydrogen absorbing layer 303, the material of the hydrogen-rich sealing insulation layer 304 may include, for example, Si₃N₄:H and the like, the thickness is not less than 100 nm.

Step 205, as shown in FIG. 3e, the hydrogen absorbing layer 303 and the hydrogen-rich sealing insulation layer 304 are patterned, parts of the hydrogen absorbing layer and the hydrogen-rich sealing insulation layer are removed, to expose the channel region 3021.

Step 206, as shown in FIG. 3f, a top gate dielectric layer 305 is deposited on the channel region 3021 and the hydrogen-rich sealing insulation layer 304. The material of the top gate dielectric layer 305 may be SiO₂, Al₂O₃, HfOₓ, and so forth, with a thickness of not less than 1 nm.

Step 207, the structure formed by the foregoing processes is subjected to an annealing operation. The annealing temperature may be 300° C.˜400° C. The annealing atmosphere is oxygen (O₂). During the annealing process, oxygen can enter the channel region 3021 of the active layer through the top gate dielectric layer 305, and defects such as oxygen vacancies are repaired, so as to make the channel region 3021 highly resistive; at the same time, hydrogen impurities in the channel region 3021 may also be vented out through the top gate dielectric layer 305.

According to an embodiment, the hydrogen absorbing layer 303 is capable of absorbing hydrogen impurities from the hydrogen-rich sealing insulation layer 304 and the intermediate channel region 3021, ensuring a low hydrogen content of the channel region 3021, and forming a highly resistive channel region. Under the influence of concentration gradient and temperature, the hydrogen impurities absorbed by the hydrogen absorbing layer 303 diffuses into the source region 3022 and the drain region 3023, to form highly conductive source region and drain region, thereby precisely regulating the distribution of hydrogen in the metal oxide, reducing the hydrogen content in the channel region 3021, and increasing the hydrogen content in the source region 3022 and the drain region 3023.

Step 208, as shown in FIG. 3g, the top gate dielectric layer 305 and the hydrogen-rich sealing insulation layer 304 are patterned, to form a source contact hole 3061 and a drain contact hole 3062.

According to an embodiment, the source contact hole 3061 and the drain contact hole 3062 may extend downward, and directly contact the source region and the drain regions in the active layer 302 respectively.

Step 209, as shown in FIG. 3h, a metal layer is deposited on the top gate dielectric layer 305 and in the source contact hole 3061 and the drain contact hole 3062, and the metal layer is patterned, to form a top gate 308, and a source electrode 3071 and a drain electrode 3072 at least penetrating into the source contact hole 3061 and the drain contact hole 3062, the material may be Mo, and the thickness is not less than 20 nm.

According to an embodiment, the step 209 may adopt another implementation mode, specifically comprising: a metal electrode is deposited in the source contact hole 3061 and the drain contact hole 3062 and a lift-off process is performed, to form a source electrode 3071 and a drain electrode 3072. A metal layer is deposited on the top gate dielectric layer 305, and patterned, to form a top gate 308.

According to an embodiment, the width of the top gate 308 is greater than the width of the channel region 3021, and there is some amount of overlap between the top gate 308 and the source region 3022, the drain region 3023. However, a hydrogen-rich sealing insulation layer 304 having a thickness of not less than 100 nm is introduced under the top gate dielectric layer 305, so that the overlap capacitance between the top gate 308 and the source region 3022, drain region 3023 is negligibly small, forming a pseudo-self-aligned device structure.

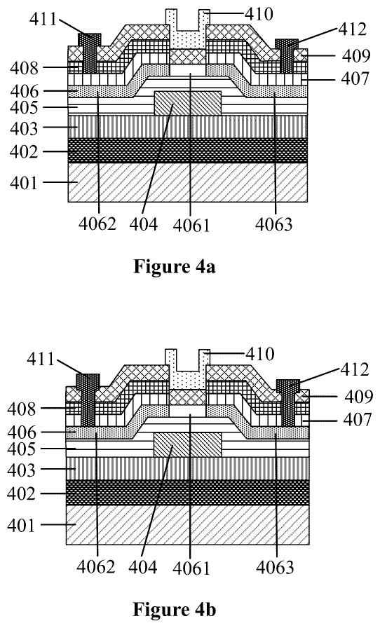

FIG. 4a to FIG. 4b are cross-sectional views of the structure of a dual gate oxide thin film transistor according to an embodiment of the present application.

According to an embodiment, the dual gate oxide thin film transistor may comprise a substrate 401.

According to an embodiment, the dual gate oxide thin film transistor may further comprise a hydrogen barrier layer 402, located on the substrate 401, with a thickness of not less than 1 nm. According to an embodiment, the material of hydrogen barrier layer 402 may include highly dense Al₂O₃, HfOₓ, or a stack of HfOₓ and Al₂O₃. After being absorbed by Al₂O₃, HfOₓ, hydrogen combines with oxygen vacancies or oxygen atoms in the Al₂O₃, HfOₓ, so that the amount of hydrogen diffused into the TFT is reduced. Thus, the hydrogen barrier layer 402 may improve the hydrogen resistance of the TFT.

According to an embodiment, the dual gate oxide thin film transistor may further comprise a buffer layer 403, located on the hydrogen barrier layer 402, having a thickness greater than 1 nm. The material of the buffer layer 403 may include SiO₂, SiNₓ, Al₂O₃, HfOₓ, or the like, or a stack of the foregoing materials.

According to an embodiment, the dual gate oxide thin film transistor may further comprise a back gate electrode 404, located on the buffer layer 403. The material of the back gate electrode 404 may include Mo.

According to an embodiment, the dual gate oxide thin film transistor may further comprise a back gate dielectric layer 405, located on the buffer layer 403 and the back gate electrode 404. The material of the back gate dielectric layer 405 may include SiO₂, Al₂O₃, HfOₓ, and the like.

According to an embodiment, the dual gate oxide thin film transistor may further comprise an active layer 406, located on the back gate dielectric layer 405, the material of the active layer 406 may include a-IGZO, a-IZO, a-IGO, and so forth, and has a thickness of not less than 1 nm. The active layer 406 may comprise a channel region 4061, a source region 4062 and a drain region 4063.

According to an embodiment, the dual gate oxide thin film transistor may further comprise a hydrogen absorbing layer 407, located on the active layer 406. The hydrogen absorbing layer 407 comprises two portions separated from each other, and the hydrogen absorbing layer above the channel region 4061 is removed. The hydrogen-absorbing layer 407 may adopt an indium-rich metal oxide having a good conductivity, such as IZO or In₂O₃ having a high indium composition.

According to an embodiment, the dual gate oxide thin film transistor may further comprise a hydrogen-rich sealing insulation layer 408, located on the hydrogen absorbing layer 407. The material of hydrogen-rich sealing insulation layer 408 may include, for example, Si₃N₄:H and the like. The hydrogen-rich sealing insulation layer 408 comprises two portions separated from each other, and the hydrogen-rich sealing insulation layer above the channel region 4061 is removed.

Since hydrogen has high chemical activity, can combine with oxygen in the indium-rich metal oxide to form an H—O bond or with In in the Indium-rich metal oxide to form an In—H bond, therefore the hydrogen absorbing layer 407 can absorb hydrogen impurities. In addition, besides absorbing hydrogen impurities in the channel region 4061 and hydrogen-rich sealing insulation layer 408, increasing the concentration of the carriers in the source region and the drain region, the hydrogen absorbing layer 407 can also directly contact with the metal oxide in the source region and the drain region of the active layer 406, so as to further improve the conductivity of the source region and the drain region.

According to an embodiment, the hydrogen absorbing layer 407 is capable of absorbing hydrogen impurities from the hydrogen-rich sealing insulation layer 408 and the channel region 4061, ensuring a low hydrogen content of the channel region 4061, forming a highly resistive channel region. The hydrogen absorbing layer 407 absorbs hydrogen impurities, and the hydrogen content is increased, while the hydrogen content in the source region 4062 and the drain region 4063 is lower. Thus, a concentration gradient is created between hydrogen contents in the hydrogen absorbing layer 407 and that in the source region 4062, the drain region 4063. Under the influence of concentration gradient and temperature, the hydrogen impurities absorbed by the hydrogen absorbing layer 407 diffuse into the source region 4062 and the drain region 4063, to form highly conductive source region and drain region, thereby precisely regulating the distribution of hydrogen in the metal oxide, reducing the hydrogen content in the channel region 4061, and increasing the hydrogen content in the source region 4062 and the drain region 4063. Such a structure can improve the conductivity of the source region and the drain region, avoid the process of forming highly conductive source region and drain region by defects generated by plasma bombardment in the existing schemes, and avoid the influence of source and drain defects on the channel region.

According to an embodiment, the dual gate oxide thin film transistor may further comprise a top gate dielectric layer 409, located on the hydrogen-rich sealing insulation layer 408 and the channel region 4061. The material of the top gate dielectric layer 409 may include a material having air permeability such as SiO₂, Al₂O₃, HfOₓ, and so forth. The hydrogen of the channel region 4061 may also be vented out through the top gate dielectric layer 409 during the transistor manufacturing process, ensuring a low hydrogen content of the channel region 4061.

According to an embodiment, the dual gate oxide thin film transistor may further comprise a top gate 410, having a width greater than the width of the channel region 4061. There is some amount of overlap between the top gate 410 and the source region 4062, drain region 4063. However, a hydrogen-rich sealing insulation layer 408 having a thickness of not less than 100 nm is introduced under the top gate dielectric layer 409, so that the overlap capacitance between the top gate 410 and the source region 4062, drain region 4063 is negligibly small, forming a pseudo-self-aligned device structure.

According to an embodiment, the dual gate oxide thin film transistor may further comprise a source electrode 411 and a drain electrode 412, and the material may include Mo, having a thickness of not less than 20 nm.

According to an embodiment, as shown in FIG. 4b, the source 411 and drain 412 may extend downward, and directly contact the source region and the drain region in the active layer 406 respectively.

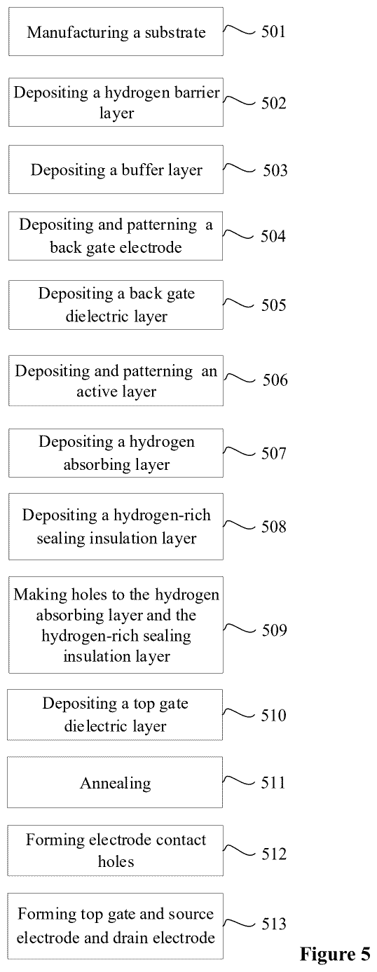

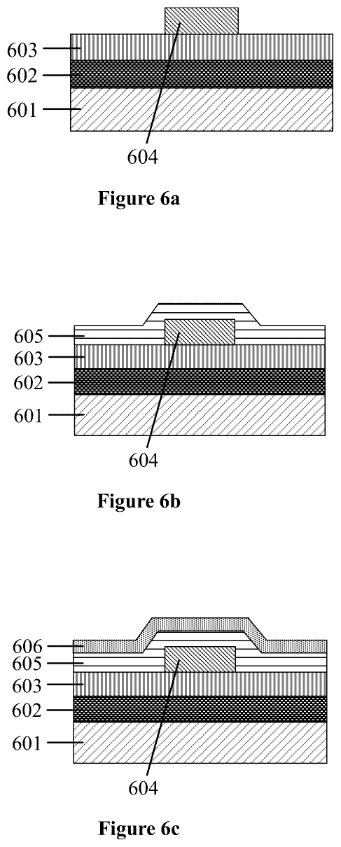

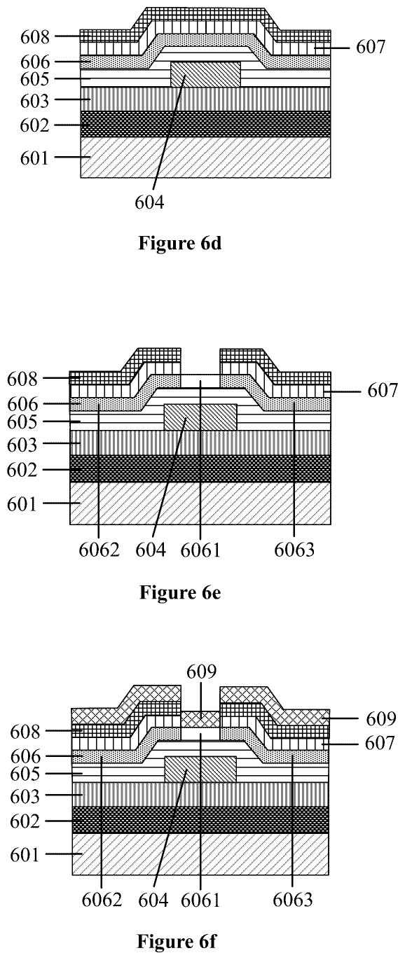

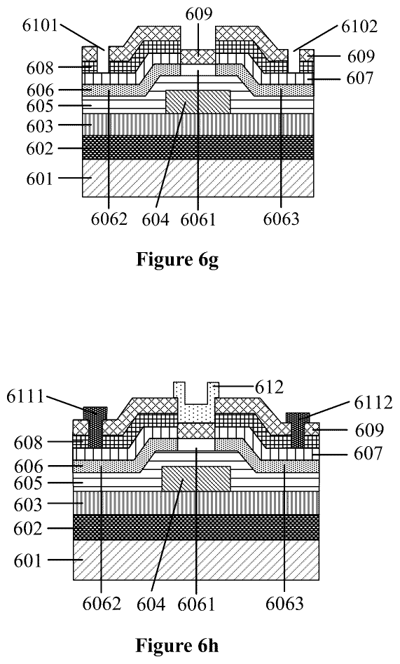

FIG. 5 is a flow diagram of a manufacturing method of a dual gate oxide thin film transistor according to an embodiment of the present application. FIG. 6a to FIG. 6h are manufacturing state diagrams of the dual gate oxide thin film transistor of the embodiment shown in FIG. 4a to FIG. 4b.

Step 501, a substrate 601 is manufactured.

Step 502, a hydrogen barrier layer 602 is deposited on the substrate 601, and the material of the hydrogen barrier layer 602 may include highly dense Al₂O₃, HfOₓ, or a stack of HfOₓ and Al₂O₃, and the thickness thereof is not less than 10 nm. The hydrogen barrier layer may improve the hydrogen resistance of the TFT.

Step 503, a buffer layer 603 is deposited on the hydrogen barrier layer 602, and the material may be SiO₂, SiNₓ, Al₂O₃, HfOₓ, or the like, or a stack of the foregoing materials, and has the thickness of greater than 1 nm.

Step 504, as shown in FIG. 6a, a back gate electrode 604 is deposited on the buffer layer 603, the material of the back gate electrode 604 may include Mo, and has a thickness of not less than 20 nm. The back gate electrode 604 is patterned, to form a back gate electrode pattern.

Step 505, as shown in FIG. 6b, a back gate dielectric layer 605 is deposited on the buffer layer 603 and the back gate electrode 604, the material of the back gate dielectric layer 605 can include SiO₂, Al₂O₃, HfOₓ, and so forth, and has the thickness of not less than 1 nm.

Step 506, as shown in FIG. 6c, an active layer 606 is deposited on the back gate dielectric layer 605, the material of the active layer 606 may include a-IGZO, a-IZO, a-IGO, and so forth, and the thickness thereof is not less than 1 nm, and then the active layer 606 is patterned, to form active islands.

Step 507, a hydrogen absorbing layer 607 is deposited on the active layer 606. Since the indium (In)-rich material has a strong binding ability with hydrogen, the material of the hydrogen absorbing layer 607 may include an indium-rich metal oxide with a good conductivity, such as IZO or In₂O₃ having a high indium composition.

Step 508, as shown in FIG. 6d, a hydrogen-rich sealing insulation layer 608 is deposited on the hydrogen absorbing layer 607. The material of the hydrogen-rich sealing insulation layer 608 may include, for example, Si₃N₄:H and the like, the thickness is not less than 100 nm.

Step 509, as shown in FIG. 6e, the hydrogen absorbing layer 607 and the hydrogen-rich sealing insulation layer 608 are patterned, parts of the hydrogen absorbing layer and the hydrogen-rich sealing insulation layer are removed, to expose the channel region 6061.

Step 510, as shown in FIG. 6f, a top gate dielectric layer 609 is deposited on the channel region 6061 and the hydrogen-rich sealing insulation layer 608. The material of the top gate dielectric layer 609 may be SiO₂, Al₂O₃, HfOₓ, and so forth, with a thickness of not less than 1 nm.

Step 511, the structure formed by the foregoing processes is subjected to anneal. The annealing temperature is at 300° C.˜400° C. The annealing atmosphere is O₂. During the annealing process, oxygen can enter the channel region 6061 of the active layer through the top gate dielectric layer 609, and defects such as oxygen vacancies are repaired, so as to make the channel region 6061 highly resistive; at the same time, hydrogen impurities in the channel region 6061 may also be vented out through the top gate dielectric layer 609.

According to an embodiment, the hydrogen absorbing layer 607 is capable of absorbing hydrogen impurities from the hydrogen-rich sealing insulation layer 608 and the intermediate channel region 6061, ensuring a low hydrogen content of the channel region 6061, and forming a highly resistive channel region. Under the influence of concentration gradient and temperature, the hydrogen impurities absorbed by the hydrogen absorbing layer 607 diffuse into the source region 6062 and the drain region 6063, to form highly conductive source region and drain region, thereby precisely regulating the distribution of hydrogen in the metal oxide, reducing the hydrogen content in the channel region 6061, and increasing the hydrogen content in the source region 6062 and the drain region 6063.

Step 512, as shown in FIG. 6g, the top gate dielectric layer 609 and the hydrogen-rich sealing insulation layer 608 are patterned, to form a source contact hole 6101 and a drain contact hole 6102.

According to an embodiment, the source contact hole 6101 and the drain contact hole 6102 may extend downward, and directly contact the source region and the drain region in the active layer 606 respectively.

Step 513, as shown in FIG. 6h, a metal layer is deposited on the top gate dielectric layer 609 and in the source contact hole 6101 and the drain contact hole 6102, and patterning is performed, to form a top gate 612, and a source electrode 6111 and a drain electrode 6112 at least penetrating into the source contact hole 6101 and the drain contact hole 6102, the material may be Mo, and the thickness is not less than 20 nm.

According to an embodiment, the step 513 may adopt another implementation mode, specifically comprising: a metal electrode is deposited in the source contact hole 6101 and the drain contact hole 6102 and a lift-off process is performed, to form a source electrode 6111 and a drain electrode 6112. A metal layer is deposited on the top gate dielectric layer 609, and patterned, to form a top gate 612.

According to an embodiment, the width of the top gate 612 is greater than the width of the channel region 6061, and there is some amount of overlap between the top gate 612 and the source region 6062, the drain region 6063. However, a hydrogen-rich sealing insulation layer 608 having a thickness of not less than 100 nm is introduced under the top gate dielectric layer 609, so that the overlap capacitance between the top gate 612 and the source region 6062, drain region 6063 is negligibly small, forming a pseudo-self-aligned device structure.

Adopting the solution of the present application may avoid forming the source region and the drain region by means of plasma bombardment, the formation of defects in the source region and the drain region can be reduced, at the same time the formation of low resistive source region and drain region can be ensured. In addition, since controlling the thickness of the hydrogen-rich sealing insulation layer to a relatively thick dimension, excessive gate to source or gate to drain overlap capacitance can be avoided, forming a pseudo-self-aligned transistor.

While the above-mentioned embodiments are merely for purposes of illustration and description of the present application, and not for limiting the present application, it will be apparent to those skilled in the art that various changes and modifications may be made without departing from the scope of the present application, accordingly, it is intended to embrace all such equivalents that fall within the scope of the present application.

1. An oxide thin film transistor, comprising:
a substrate;
an active layer, located on the substrate, comprising a channel region and a source region and a drain region, wherein carriers in the source region and the drain region include hydrogen;
a hydrogen absorbing layer, located on the active layer, wherein a portion of the hydrogen absorbing layer located on the channel region is removed;
a hydrogen-rich sealing insulation layer, located on the hydrogen absorbing layer, wherein a portion of the hydrogen-rich sealing insulation layer located above the channel region is removed;
a top gate dielectric layer, located on the hydrogen-rich sealing insulation layer and the channel region;
a top gate, located on the top gate dielectric layer; and
a source electrode and a drain electrode, respectively in contact with the hydrogen absorbing layer on both sides of the channel region.

2. The oxide thin film transistor according to claim 1, further comprising
a hydrogen barrier layer, located on the substrate; and
a buffer layer, located on the hydrogen barrier layer;
wherein, the active layer is located above the buffer layer.

3. The oxide thin film transistor according to claim 2, further comprising:
a back gate electrode, located on the buffer layer; and
a back gate dielectric layer, located on the buffer layer and the back gate electrode;
wherein, the active layer is located on the back gate dielectric layer.

4. The oxide thin film transistor according to any one of claim 1 to 3, wherein the source electrode and the drain electrode are further in contact with the source region and drain region below the hydrogen absorbing layer respectively.

5. The oxide thin film transistor according to any one of claim 1 to 3, wherein width of the top gate is greater than width of the channel region.

6. The oxide thin film transistor according to any one of claim 1 to 3, wherein material of the active layer includes an amorphous metal oxide, and the material of the hydrogen absorbing layer includes an indium-rich metal oxide.

7. The oxide thin film transistor according to any one of claim 1 to 3, wherein the material of the hydrogen-rich sealing insulation layer includes hydrogen-rich silicon nitride.

8. The oxide thin film transistor according to any one of claim 1 to 3, wherein the top gate dielectric layer is an air permeable insulating material.

9. A manufacturing method of an oxide thin film transistor, comprising:
manufacturing a substrate; depositing an active layer on the substrate, and patterning the active layer;
depositing a hydrogen absorbing layer on the active layer;
depositing a hydrogen-rich sealing insulation layer on the hydrogen absorbing layer;
patterning the hydrogen absorbing layer and the hydrogen-rich sealing insulation layer, removing the hydrogen absorbing layer on the channel region and the hydrogen-rich sealing insulation layer above the channel region, and exposing the channel region;
depositing a top gate dielectric layer on the channel region of the active layer and the hydrogen-rich sealing insulation layer, and performing an annealing operation, wherein the hydrogen absorbing layer is configured to absorb hydrogen from the channel region, and affected by hydrogen concentration gradient and temperature, the hydrogen absorbed by the hydrogen absorbing layer is configured to diffuse to the source region and the drain region;
patterning the top gate dielectric layer and the hydrogen-rich sealing insulation layer to form source and drain electrode contact holes; and
depositing and patterning a metal layer on the top gate dielectric layer, to form a top gate, and a source electrode and a drain electrode penetrating at least into the source and drain electrode contact holes.

10. The manufacturing method of an oxide thin film transistor according to claim 9, further comprising:
depositing a hydrogen barrier layer on the substrate;
depositing a buffer layer on the hydrogen barrier layer; and
depositing the active layer on the buffer layer, and patterning the active layer.

11. A manufacturing method of an oxide thin film transistor, comprising:
manufacturing a substrate;
depositing a buffer layer on the substrate;
depositing and patterning a first metal layer on the buffer layer, to form a back gate;
depositing a back gate dielectric layer on the back gate and the buffer layer;
depositing an active layer on the back gate dielectric layer, and patterning the active layer;
depositing a hydrogen absorbing layer on the active layer;
depositing a hydrogen-rich sealing insulation layer on the hydrogen absorbing layer;
patterning the hydrogen absorbing layer and the hydrogen-rich sealing insulation layer, removing the hydrogen-absorbing layer on the channel region and the hydrogen-rich sealing insulation layer above the channel region, and exposing the channel region;
depositing a top gate dielectric layer on the channel region of the active layer and the hydrogen-rich sealing insulation layer, and performing an annealing operation, wherein the hydrogen absorbing layer is configured to absorb hydrogen from the channel region, and affected by hydrogen concentration gradient and temperature, the hydrogen absorbed by the hydrogen absorbing layer is configured to diffuse to the source region and the drain region;
patterning the top gate dielectric layer and the hydrogen-rich sealing insulation layer, to form source and drain electrode contact holes; and
depositing and patterning a second metal layer on the top gate dielectric layer, to form a top gate, and a source electrode and a drain electrode penetrating at least into the source and drain electrode contact holes.

12. The manufacturing method of an oxide thin film transistor according to Claim 11, further comprising:
depositing a hydrogen barrier layer on the substrate; and
depositing a buffer layer on the hydrogen barrier layer.
